(19) United States
(12) Patent Application Publication
(10) Pub. No.: US 2015/0292088 A1
(43) Pub. Date: Oct. 15, 2015

(54) DEPOSITION SYSTEMS HAVING INTERCHANGEABLE GAS INJECTORS AND RELATED METHODS

(71) Applicants: Claudio CANIZARES, (US); SOITEC, Crolles Cedex (FR)

(72) Inventor: Claudio Canizares, Chandler, AZ (US)

(21) Appl. No.: 14/443,202

(22) PCT Filed: Nov. 20, 2013
(86) PCT No.: PCT/IB2013/002604

§ 371 Date: May 15, 2015

Related U.S. Application Data
(60) Provisional application No. 61/730,393, filed on Nov. 27, 2012.

(51) Int. Cl. C23C 16/455; H01L 21/02; B23P 19/04

(52) U.S. Cl. CPC C23C 16/45563; B23P 19/04; C23C 16/45504; H01L 21/0262

(57) ABSTRACT

A deposition system includes two or more gas injectors that may be interchangeably used in a chamber of the deposition system. Each of the gas injectors may be configured to generate a sheet of flowing gas over a substrate support structure. The sheets may have differing widths, such that the gas injectors may be used with substrates having different diameters, which may enable use of the system with different substrates while maintaining efficient use of precursor gas. A method of forming such a deposition system includes forming and configuring such gas injectors to be interchangeably used at a common location within the deposition chamber. A method of using such a deposition system includes using two or more such gas injectors to deposit material on substrates having different sizes.

### CROSS-REFERENCE TO RELATED APPLICATIONS

This application is a national phase entry under 35 U.S.C. §371 of International Patent Application PCT/IB2013/002604, filed Nov. 20, 2013, designating the United States of America and published in English as International Patent Publication WO 2014/083400 A1 on Jun. 5, 2014, which claims the benefit under Article 8 of the Patent Cooperation Treaty and under 35 U.S.C. §119(e) to U.S. Provisional Patent Application Ser. No. 61/730,393, filed Nov. 27, 2012, the disclosure of each of which is hereby incorporated herein in its entirety by this reference.

### TECHNICAL FIELD

The present disclosure relates to deposition systems that have interchangeable gas injectors, as well as to methods of making and using such deposition systems.

### BACKGROUND

Semiconductor structures are structures that are used or formed in the fabrication of semiconductor devices. Semiconductor devices include, for example, electronic signal processors, electronic memory devices, photoactive devices (e.g., light emitting diodes (LEDs), photovoltaic (PV) devices, etc.), and microelectromechanical (MEM) devices. Such structures and materials often include one or more semiconductor materials (e.g., silicon, germanium, silicon carbide, a III-V semiconductor material, etc.), and may include at least a portion of an integrated circuit.

Semiconductor structures are often fabricated using any of a number of chemical deposition processes and systems. For example, chemical vapor deposition (CVD) is a chemical deposition process that is used to deposit solid materials on substrates, and is commonly employed in the manufacture of semiconductor structures. In chemical vapor deposition processes, a substrate is exposed to one or more reagent gases, which react, decompose, or both react and decompose in a manner that results in the deposition of a solid material on the surface of the substrate.

One particular type of CVD process is referred to in the art as vapor phase epitaxy (VPE). In VPE processes, a substrate is exposed to one or more reagent vapors in a deposition chamber, which react, decompose, or both react and decompose in a manner that results in the epitaxial deposition of a solid material on the surface of the substrate. VPE processes are often used to deposit III-V semiconductor materials. When one of the reagent vapors in a VPE process comprises a hydride vapor, the process may be referred to as a hydride vapor phase epitaxy (HVPE) process.

HVPE processes are used to form III-V semiconductor materials such as, for example, gallium nitride (GaN). As an example, epitaxial growth of GaN on a substrate results from a vapor phase reaction between gallium chloride (GaCl) vapor and ammonia (NH₃) that is carried out within a deposition chamber at elevated temperatures between about 500° C. and about 1,100° C. The NH₃ may be supplied from a standard source of NH₃ gas.

In some methods, the GaCl vapor is provided by passing hydrogen chloride (HCl) gas (which may be supplied from a standard source of HCl gas) over heated liquid gallium (Ga) to form GaCl in situ within the deposition chamber. The liquid gallium may be heated to a temperature of between about 750° C. and about 850° C. The GaCl and the NH₃ may be directed to (e.g., over) a surface of a heated substrate, such as a wafer of semiconductor material. U.S. Pat. No. 6,179,913, which issued Jan. 30, 2001 to Solomon et al., discloses a gas injection system for use in such systems and methods. In such systems, it may be necessary to open the deposition chamber to atmosphere to replenish the source of liquid gallium. Furthermore, it may not be possible to clean the deposition chamber in situ in such systems.

To address such issues, methods and systems have been developed that utilize an external source of a GaCl₃ precursor which is thermally decomposed to form GaCl (and the byproduct Cl₂), which is directly injected into the deposition chamber. Examples of such methods and systems are disclosed in, for example, U.S. Patent Application Publication No. U.S. 2009/0223442 A1, which published Sep. 10, 2009 in the name of Arena et al.

In prior known configurations, the precursor GaCl may be injected into the chamber through a generally planar gas injector having diverging internal sidewalls (often referred to as a “visor” or “visor injector”). The precursor NH₃ may be injected into the chamber through a multi-port injector. Upon injection into the chamber, the precursors are initially separated by a top plate of the visor injector that extends to a location proximate an edge of the substrate. When the precursors reach the end of the top plate, the precursors mix and react to form a layer of GaN material on the substrate.

### BRIEF SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments, the present disclosure includes deposition systems that have a deposition chamber, a substrate support structure having an upper support surface configured to support a substrate within the deposition chamber, and at least two gas injectors each configured to be interchangeably seated at a common location within the deposition chamber. Each of the at least two gas injectors may be configured to generate a sheet of generally laminar flowing gas over the substrate support structure during operation of the deposition system. A first gas injector of the at least two gas injectors may include two adjoining plates defining one or more gas flow channels between the adjoining plates. The one or more gas flow channels of the first gas injector may be located and configured to generate a sheet of generally laminar flowing gas having a first maximum width transverse to a direction of gas flow in a gas flow plane parallel to the upper support surface of the substrate support structure. A second gas injector of the at least two gas injectors may include two adjoining plates defining one or more gas flow channels between the adjoining plates. The one or more gas flow channels of the second gas injector may be located and configured to generate a second sheet of generally laminar flowing gas having a second maximum width, which may be smaller than the first maximum width, transverse to the direction of gas flow in the gas flow plane.

In other embodiments, the present disclosure includes methods of fabricating deposition systems as described herein. In accordance with such methods, a deposition chamber may be provided, and a substrate support structure may be provided within the deposition chamber. The substrate support structure may have an upper support surface configured to support a substrate. A first gas injector may be formed by forming two plates and adjoining the two plates together such that one or more gas flow channels are defined between the adjoined plates. The one or more gas flow channels may be located and configured to generate a first sheet of generally laminar flowing gas having a first maximum width transverse to a direction of gas flow in a gas flow plane parallel to the upper support surface of the substrate support structure. A second gas injector may be formed by forming two plates and adjoining the two plates together such that one or more gas flow channels are defined between the adjoined plates. The one or more gas flow channels may be located and configured to generate a second sheet of generally laminar flowing gas having a second maximum width, which may be smaller than the first maximum width, transverse to the direction of gas flow in the gas flow plane parallel to the upper support surface of the substrate support structure. The first gas injector and the second gas injector may be configured to be interchangeably used at a common location within the deposition chamber.

In yet further embodiments, the present disclosure includes methods of using deposition systems as described herein. In accordance with such methods, a first gas injector may be installed within a deposition chamber. The first gas injector may comprise two adjoining plates defining one or more gas flow channels between the two adjoining plates. A first substrate may be positioned within the deposition chamber, and a first sheet of generally laminar flowing gas may be generated over the first substrate using the first gas injector to deposit material on the first substrate using the first sheet of generally laminar flowing gas. The first sheet of generally laminar flowing gas may have a first maximum width transverse to a direction of gas flow in the first sheet of generally laminar flowing gas. The first substrate may be removed from the deposition chamber after depositing material on the first substrate, and a second gas injector may be installed within the deposition chamber. The second gas injector may comprise two adjoining plates defining one or more gas flow channels between the two adjoining plates. A second substrate may be positioned within the deposition chamber. The second substrate may have a diameter smaller than a diameter of the first substrate. After the second substrate is positioned within the deposition chamber, a second sheet of generally laminar flowing gas may be generated over the second substrate using the second gas injector to deposit material on the second substrate using the second sheet of generally laminar flowing gas. The second sheet of generally laminar flowing gas may have a second maximum width transverse to a direction of gas flow in the second sheet of generally laminar flowing gas, and the second maximum width may be smaller than the first maximum width.

### BRIEF DESCRIPTION OF THE DRAWINGS

FIG. 1A is a cut-away perspective view schematically illustrating an example embodiment of a deposition system including a gas injector according to embodiments of the present disclosure.

FIG. 1B is a cut-away perspective view schematically illustrating another example embodiment of a deposition system including a gas injector according to embodiments of the present disclosure.

FIG. 2 is an exploded perspective view of a first gas injector that may be used with either of the deposition systems shown in FIG. 1A and FIG. 1B, which includes a base plate, a middle plate, and a top plate.

FIG. 3 is a top view of the base plate of FIG. 2.

FIG. 4 is a top view of the top plate of FIG. 2.

FIG. 5 is a bottom view of the middle plate of FIG. 2 showing purge gas flow channels formed therein.

FIG. 6 is a top view of the middle plate of FIG. 2 showing precursor gas flow channels formed therein.

FIG. 7 is a partial cross-sectional view of a portion of the gas injector of FIG. 2 when assembled, including the base plate, the middle plate, the top plate, and a weld coupling the middle plate to the top plate along peripheral edges of the middle plate and top plate.

FIG. 8 is an exploded perspective view of a second gas injector that may be used with either of the deposition systems shown in FIG. 1A and FIG. 1B.

FIG. 9 is a top plan view of the middle plate of FIG. 8 showing precursor gas flow channels formed therein.

FIG. 10 is an exploded perspective view of a third gas injector that may be used with either of the deposition systems shown in FIG. 1A and FIG. 1B.

FIG. 11 is a top plan view of the middle plate of FIG. 10 showing precursor gas flow channels formed therein.

### DETAILED DESCRIPTION

The illustrations presented herein are not meant to be actual views of any particular deposition system, gas injector, or component thereof, but are merely idealized representations that are used to describe embodiments of the disclosure.

As used herein, the term “substantially,” in reference to a given parameter, property, or condition, means to a degree that one of ordinary skill in the art would understand that the given parameter, property, or condition is met within a degree of variance, such as within acceptable manufacturing tolerances.

As used herein, the term “gas” means and includes a fluid that has neither independent shape nor volume. Gases include vapors. Thus, when the term “gas” is used herein, it may be interpreted as meaning “gas or vapor.”

As used herein, the phrase “gallium chloride” means and includes one or more of gallium monochloride (GaCl) and gallium trichloride, which may exist in monomer form (GaCl₃) or in dimer form (Ga₂Cl₆). For example, gallium chloride may be substantially comprised of gallium monochloride, substantially comprised of gallium trichloride, or substantially comprised of both gallium monochloride and gallium trichloride.

The present disclosure includes systems, devices, and methods that may be used to flow gas toward a substrate for depositing or otherwise forming a material (e.g., a semiconductor material) on a surface of the substrate using the gas. Examples of such systems, devices, and methods are disclosed in further detail below.

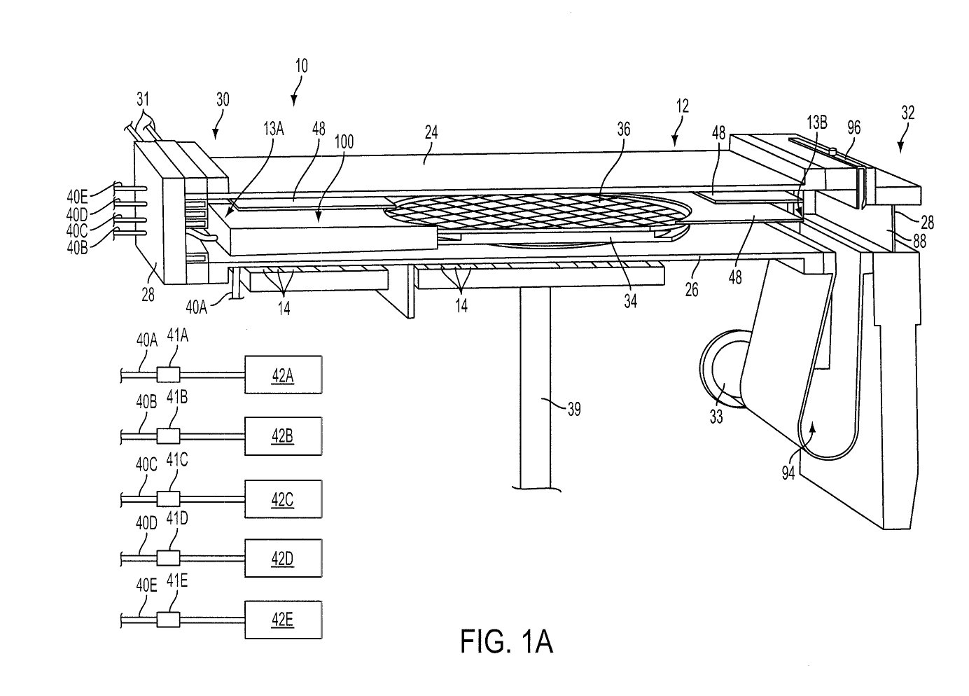

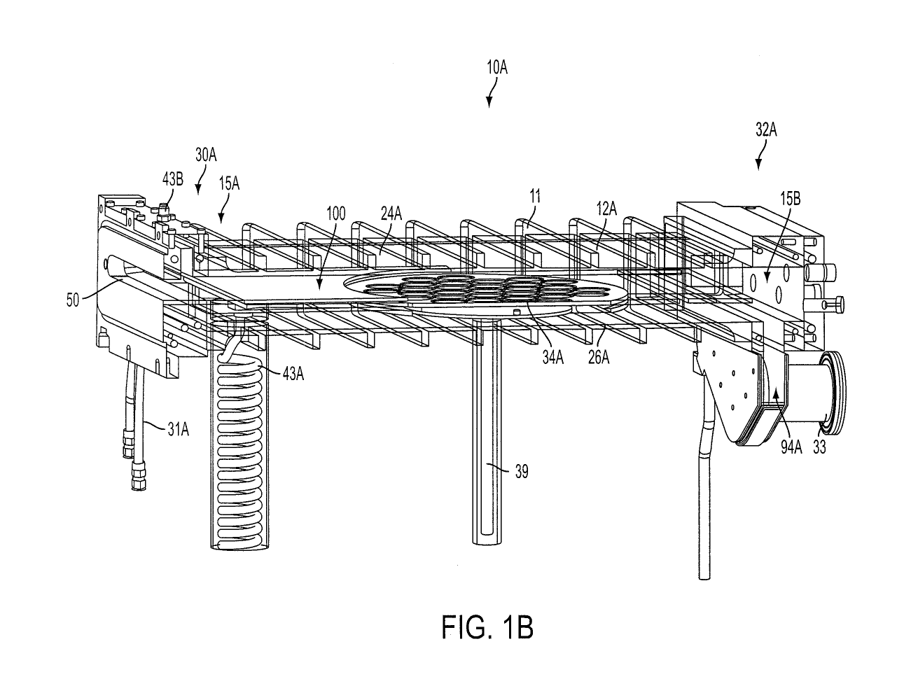

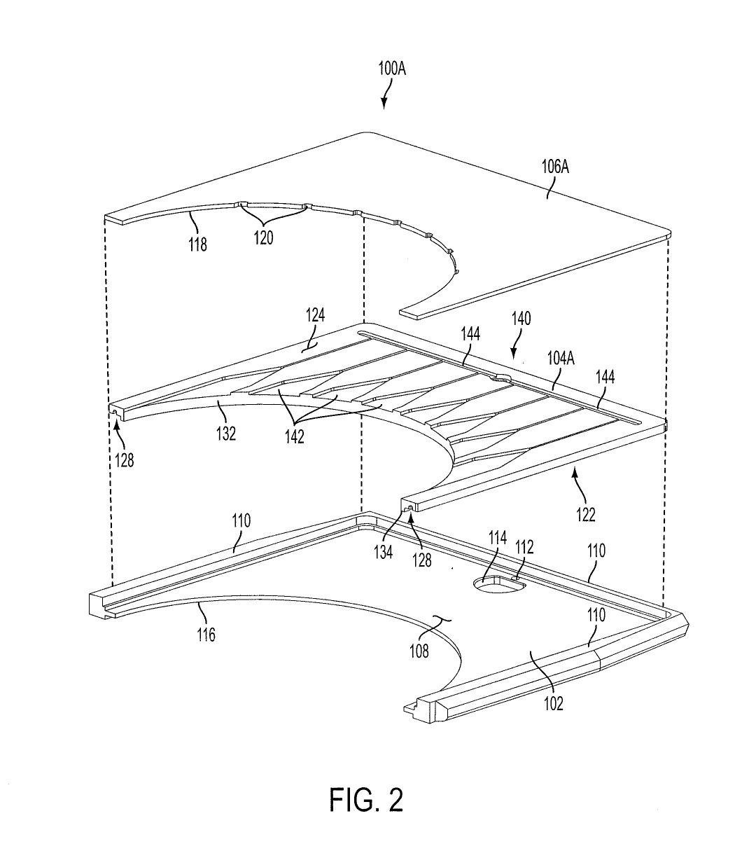

FIG. 1A illustrates an example of a deposition system 10 in accordance with the present disclosure. The deposition system 10 includes an at least substantially enclosed deposition chamber 12, a substrate support structure 34 having an upper support surface configured to support a substrate 36 within the deposition chamber 12, and at least two gas injectors 100 (only one of which is shown in FIG. 1A) configured to be interchangeably seated at a common location within the deposition chamber 12. Such gas injectors 100 are described in further detail herein with reference to FIGS. 2 through 11. In some embodiments, the deposition system 10 may comprise a CVD system, and may comprise a VPE deposition system (e.g., an HYPE deposition system).

The deposition chamber 12 may include one or more chamber walls. For example, the chamber walls may include a horizontally oriented top wall 24, a horizontally oriented bottom wall 26, and one or more vertically oriented lateral side walls 28 extending between the top wall 24 and the bottom wall 26. In some embodiments, the deposition chamber 12 may have the geometric shape of an elongated rectangular prism, as shown in FIG. 1A. In other embodiments, the deposition chamber 12 may have another geometric shape.

The deposition system 10 includes a substrate support structure 34 (e.g., a susceptor) having an upper support surface configured to support one or more workpiece substrates 36 within the deposition chamber 12 on which it is desired to deposit or otherwise provide semiconductor material within the deposition system 10. For example, the one or more workpiece substrates 36 may comprise dies or wafers. As shown in FIG. 1A, the substrate support structure 34 may be coupled to a spindle 39, which may be coupled (e.g., directly structurally coupled, magnetically coupled, etc.) to a drive device (not shown), such as an electrical motor that is configured to drive rotation of the spindle 39 and, hence, the substrate support structure 34 and the workpiece substrate or substrates 36 supported thereon within the deposition chamber 12.

The deposition system 10 further includes a gas flow system used to flow process gases through the deposition chamber 12. For example, the deposition system 10 may comprise at least one gas injection system 30 for injecting one or more process gases into the deposition chamber 12 at a first location 13A, and a venting and loading subassembly 32 including a vacuum device 33 for drawing the one or more process gases through the deposition chamber 12 from the first location 13A to a second location 13B and for evacuating the one or more process gases out from the deposition chamber 12 at the second location 13B. The venting and loading subassembly 32 used for venting process gases out from the deposition chamber 12 and for loading substrates into the deposition chamber 12 and unloading substrates out from the deposition chamber 12. In some embodiments, the gas injection system 30 may be located at a first end of the deposition chamber 12, and the venting and loading subassembly may be located at an opposing, second end of the deposition chamber 12, as shown in FIG. 1A.

The gas injection system 30 may comprise, for example, a gas injection manifold including connectors configured to couple with conduits carrying one or more process gases from process gas sources. As discussed in further detail below, the gas injection system 30 of the deposition system 10 further includes a set of two or more interchangeable gas injectors 100 as described herein in further detail with reference to FIGS. 2 through 11 below, which gas injectors 100 may be interchangeably seated within the deposition chamber 12 for use in deposition processes. Each of the gas injectors 100 may be configured to generate a sheet of generally laminar flowing gas over the substrate support structure 34 during operation of the deposition system 10.

With continued reference to FIG. 1A, the deposition system 10 may include five gas inflow conduits 40A-40E that carry gases from respective process gas sources 42A-42E to the gas injection system 30. Optionally, gas valves (41A-41E) may be used to selectively control the flow of gas through the gas inflow conduits 40A-40E, respectively.

In some embodiments, at least one of the gas sources 42A-42E may comprise an external source of at least one of GaCl₃, InCl₃, or AlCl₃, as described in U.S. Patent Application Publication No. US 2009/0223442 A1, the disclosure of which is incorporated herein in its entirety by this reference. GaCl₃, InCl₃ and AlCl₃ may exist in the form of a dimer such as, for example, Ga₂Cl₆, In₂Cl₆ and Al₂Cl₆, respectively. Thus, at least one of the gas sources 42A-42E may comprise a dimer such as Ga₂Cl₆, In₂Cl₆ or Al₂Cl₆.

In embodiments in which one or more of the gas sources 42A-42E is, or includes, a GaCl₃ source, the GaCl₃ source may include a reservoir of liquid GaCl₃ maintained at a temperature of at least 100° C. (e.g., approximately 130° C.), and may include physical means for enhancing the evaporation rate of the liquid GaCl₃. Such physical means may include, for example, a device configured to agitate the liquid GaCl₃, a device configured to spray the liquid GaCl₃, a device configured to flow carrier gas rapidly over the liquid GaCl₃, a device configured to bubble carrier gas through the liquid GaCl₃, a device, such as a piezoelectric device, configured to ultrasonically disperse the liquid GaCl₃, and the like. As a non-limiting example, a carrier gas, such as He, N₂, H₂, or Ar, may be bubbled through the liquid GaCl₃, while the liquid GaCl₃ is maintained at a temperature of at least 100° C., such that the source gas may include one or more carrier gases in which precursor gas is conveyed.

In some embodiments, the temperatures of the gas inflow conduits 40A-40E may be controlled between the gas sources 42A-42E and the deposition chamber 12. The temperatures of the gas inflow conduits 40A-40E and associated mass flow sensors, controllers, and the like, may increase gradually from a first temperature (e.g., about 100° C. or more) at the exit from the respective gas sources 42A-42E up to a second temperature (e.g., about 150° C. or less) at the point of entry into the deposition chamber 12 in order to prevent condensation of the gases (e.g., GaCl₃ vapor) in the gas inflow conduits 40A-40E. Optionally, the length of the gas inflow conduits 40A-40E between the respective gas sources 42A-42E and the deposition chamber 12 may be about three feet or less, about two feet or less, or even about one foot or less. The pressure of the source gases may be controlled using one or more pressure control systems.

In additional embodiments, the deposition system 10 may include less than five (e.g., one to four) gas inflow conduits and respective gas sources, or the deposition system 10 may include more than five (e.g., six, seven, etc.) gas inflow conduits and respective gas sources.

The one or more of the gas inflow conduits 40A-40E extend to the gas injection system 30. The gas injection system 30 may comprise a manifold including one or more blocks of material through which the process gases are carried into the deposition chamber 12. One or more cooling conduits 31 may extend through the blocks of material. A cooling fluid may be caused to flow through the one or more cooling conduits 31 so as to maintain the gas or gases flowing through the manifold by way of the gas inflow conduits 40A-40E within a desirable temperature range during operation of the deposition system 10. For example, it may be desirable to maintain the gas or gases flowing through the manifold by way of the gas inflow conduits 40A-40E at a temperature less than about 200° C. (e.g., about 150° C.) during operation of the deposition system 10.

With continued reference to FIG. 1A, the venting and loading subassembly 32 may comprise a vacuum chamber 94 into which gases flowing through the deposition chamber 12 are drawn by a vacuum within the vacuum chamber 94 and vented out from the deposition chamber 12. The vacuum within the vacuum chamber 94 is generated by the vacuum device 33. As shown in FIG. 1A, the vacuum chamber 94 may be located below the deposition chamber 12.

The venting and loading subassembly 32 may further comprise a purge gas curtain device 96 that is configured and oriented to provide a generally planar curtain of flowing purge gas, which flows out from the purge gas curtain device 96 and into the vacuum chamber 94. The venting and loading subassembly 32 also may include an access gate 88, which may be selectively opened for loading and/or unloading workpiece substrates 36 from the substrate support structure 34, and selectively closed for processing of the workpiece substrates 36 using the deposition system 10. In some embodiments, the access gate 88 may comprise at least one plate configured to move between a closed first position and an open second position. The access gate 88 may extend through a side wall of the deposition chamber 12 in some embodiments.

The deposition chamber 12 may be at least substantially enclosed, and access to the substrate support structure 34 through the access gate 88 may be precluded, when the plate of the access gate 88 is in the closed first position. Access to the substrate support structure 34 may be enabled through the access gate 88 when the plate of the access gate 88 is in the open, second position. The purge gas curtain emitted by the purge gas curtain device 96 may reduce or prevent the flow of gases out from the deposition chamber 12 during loading and/or unloading of workpiece substrates 36.

Gaseous byproducts, carrier gases, and any excess precursor gases may be exhausted out from the deposition chamber 12 through the venting and loading subassembly 32.

The deposition system 10 may comprise a plurality of thermal radiation emitters 14, as illustrated in FIG. 1A. The thermal radiation emitters 14 are configured to emit thermal radiation within a range of wavelengths of electromagnetic radiation in at least one of the infrared region and the visible region of the electromagnetic radiation spectrum. For example, the thermal radiation emitters 14 may comprise thermal lamps (not shown) configured to emit thermal energy in the form of electromagnetic radiation. In some embodiments, the thermal radiation emitters 14 may be located outside and below the deposition chamber 12 adjacent the bottom wall 26. In additional embodiments, the thermal radiation emitters 14 may be located above the deposition chamber 12 adjacent the top wall 24, beside the deposition chamber 12 adjacent one or more lateral side walls 28, or at a combination of such locations.

The thermal radiation emitters 14 may be disposed in a plurality of rows of thermal radiation emitters 14, which may be controlled independently from one another. In other words, the thermal energy emitted by each row of thermal radiation emitters 14 may be independently controllable. The rows may be oriented transverse to the direction of the net flow of gas through the deposition chamber 12, which is the direction extending from left to right from the perspective of FIG. 1A. Thus, the independently controlled rows of thermal radiation emitters 14 may be used to provide a selected thermal gradient across the interior of the deposition chamber 12, if so desired.

The thermal radiation emitters 14 may be located outside the deposition chamber 12 and configured to emit thermal radiation through at least one chamber wall of the deposition chamber 12 and into an interior of the deposition chamber 12. Thus, at least a portion of the chamber walls through which the thermal radiation is to pass into the deposition chamber 12 may comprise a transparent material, so as to allow efficient transmission of the thermal radiation into the interior of the deposition chamber 12. The transparent material may be transparent in the sense that the material may be at least substantially transparent to electromagnetic radiation at wavelengths corresponding to the thermal radiation emitted by the thermal radiation emitters 14. For example, at least about 80%, at least about 90%, or even at least about 95% of at least a range of the wavelengths of the thermal radiation emitted by the thermal radiation emitters 14 impinging on the transparent material may pass through the transparent material and into the interior of the deposition chamber 12.

As a non-limiting example, the transparent material may comprise a transparent refractory ceramic material, such as transparent quartz (i.e., silicon dioxide (SiO₂)). The transparent quartz may be fused quartz. Any other refractory material that is both physically and chemically stable at the temperatures and in the environments to which the material is subjected during deposition processes using the deposition system 10, and that is sufficiently transparent to the thermal radiation emitted by the thermal radiation emitters 14, may be used to form one or more of the chamber walls of the deposition system 10 in further embodiments of the disclosure.

As shown in FIG. 1A, in some embodiments, the thermal radiation emitters 14 may be disposed outside and below the deposition chamber 12 adjacent the bottom wall 26 of the deposition chamber 12. In such embodiments, the bottom wall 26 may comprise a transparent material, such as transparent quartz, so as to allow transmission of the thermal radiation emitted by the thermal radiation emitters 14 into the interior of the deposition chamber 12 as described above. Of course, thermal radiation emitters 14 may be provided adjacent other chamber walls of the deposition chamber 12 and at least a portion of such chamber walls also may comprise a transparent material as described herein.

Optionally, passive heat transfer structures (e.g., structures comprising materials that behave similarly to a black body) may be located within the deposition chamber 12 to improve transfer of heat to the process gases within the deposition chamber 12.

Passive heat transfer structures (e.g., structures comprising materials that behave similarly to a black body) may be provided within the deposition chamber 12 as disclosed in, for example, U.S. Patent Application Publication No. US 2009/0214785 A1, which published on Aug. 27, 2009 in the name of Arena et al., the entire disclosure of which is incorporated herein by reference. By way of example and not limitation, one or more passive heat transfer plates 48 may be located between the top wall 24 and the bottom wall 26 of the deposition chamber 12, as shown in FIG. 1A. Such passive heat transfer plates 48 may improve the transfer of heat provided by the thermal radiation emitters 14 to the process gases within the deposition chamber 12, and may improve the homogeneity and consistency of the temperature within the deposition chamber 12. The one or more passive heat transfer plates 48 may comprise a material with high emissivity values (close to unity) (black body materials) that is also capable of withstanding the high temperature, corrosive environment that may be encountered within the deposition chamber 12. Such materials may include, for example, aluminum nitride (AlN), silicon carbide (SiC), and boron carbide (B₄C), which have emissivity values of 0.98, 0.92, and 0.92, respectively. Thus, the one or more passive heat transfer plates 48 may absorb thermal energy emitted by the thermal radiation emitters 14, and reemit the thermal energy into the deposition chamber 12 and the process gas or gases therein.

As previously mentioned, the gas injection system 30 of the deposition system 10 further includes a set of at least two gas injectors 100 each configured to be interchangeably seated at a common location within the deposition chamber 12. Each of the gas injectors 100 may be configured to generate a sheet of generally laminar flowing gas over the substrate support structure 34 during operation of the deposition system 10. Such a set of gas injectors 100 is described in further detail below with reference to FIGS. 2 through 11.

FIG. 1B illustrates an example of another deposition system 10A in accordance with an embodiment of the present disclosure. The deposition system 10A of FIG. 1B is similar to the deposition system 10 of FIG. 1A in some aspects. Thus, at least some of the same or similar numbering is used in FIG. 1B as in FIG. 1A, where appropriate, for simplicity and to illustrate similarities between the deposition system 10A of FIG. 1B and the deposition system 10 of FIG. 1A.

The deposition system 10A of FIG. 1B includes an at least substantially enclosed deposition chamber 12A, a substrate support structure 34A having an upper support surface configured to support one or more substrates within the deposition chamber 12A, and at least two gas injectors 100 (only one of which is shown in FIG. 1B) configured to be interchangeably seated at a common location within the deposition chamber 12A, as described in further detail herein with reference to FIGS. 2 through 11. The deposition chamber 12A may be at least substantially similar to the deposition chamber 12 described above with reference to FIG. 1A, although the deposition chamber 12A is shown in FIG. 1B with structural ribs 11 extending from a top wall 24A, side walls, and a bottom wall 26A thereof. The substrate support structure 34A (e.g., a susceptor) may be configured for supporting a plurality of substrates (e.g., dies, wafers) on which it is desired to deposit or otherwise provide semiconductor material within the deposition system 10A. A spindle 39 may be configured to drive rotation of the substrate support structure 34A, as described above.

The deposition system 10A further includes a gas flow system used to flow process gases through the deposition chamber 12A. For example, the deposition system 10A may include at least one gas injection system 30A for injecting one or more process gases into the deposition chamber 12A at a first location 15A, and a venting system 32A including a vacuum device 33 and a vacuum chamber 94A for drawing one or more process gases through the deposition chamber 12A from the first location 15A to a second location 15B, and for evacuating the one or more process gases out from the deposition chamber 12A at the second location 15B. The gas injection system 30A may include gas inflow conduits 43A and 43B that carry gases from process gas sources, similar to the gas inflow conduits 40A-40E of FIG. 1A, into the deposition chamber 12A. The gas inflow conduit 43A of FIG. 1B may comprise a thermalizing gas injector for generating and delivering a process gas to the deposition chamber 12A. Examples of such thermalizing gas injectors are disclosed in: U.S. Pat. No. 8,197,597, issued Jun. 12, 2012, and titled “GALLIUM TRICHLORIDE INJECTION SCHEME”; U.S. patent application Ser. No. 12/894,724, filed Sep. 30, 2010, and titled “THERMALIZING GAS INJECTORS FOR GENERATING INCREASED PRECURSOR GAS, MATERIAL DEPOSITION SYSTEMS INCLUDING SUCH INJECTORS, AND RELATED METHODS”; and U.S. Pat. No. 8,133,806, issued Mar. 13, 2012, and titled “SYSTEMS AND METHODS FOR FORMING SEMICONDUCTOR MATERIALS BY ATOMIC LAYER DEPOSITION.” The disclosure of each of these documents is incorporated herein in its entirety by this reference.

With continued reference to FIG. 1B, the gas injection system 30A may include a slot 50 for loading workpiece substrates into the deposition chamber 12A and/or for unloading workpiece substrates from the deposition chamber 12A. Thus, the loading and unloading of workpiece substrates may be accomplished proximate the first location 15A upstream of the substrate support structure 34A in the flow of process gases, rather than downstream of the substrate support structure 34 as described above with reference to FIG. 1A.

FIG. 2 illustrates an exploded perspective view of a first gas injector 100A configured to be seated within the deposition chamber 12 of the deposition system 10 of FIG. 1A or within the deposition chamber 12A of the deposition system 10A of FIG. 1B. For simplicity, FIGS. 2 through 11 are described below in relation to the deposition system 10 of FIG. 1A, although it is to be understood that the same concepts will apply to the deposition system 10A of FIG. 1B. As shown in FIG. 2, the first gas injector 100A includes a base plate 102, a middle plate 104A disposed over the base plate 102, and a top plate 106A disposed over the middle plate 104 on a side thereof opposite the base plate 102.

During operation, the gas injected by the first gas injector 100A may be heated prior to injection into the deposition chamber 12 through the first gas injector 100A. One method of heating a gallium chloride precursor gas prior to injection into the deposition chamber 12 is disclosed in International Publication No. WO 2010/101715 A1, filed Feb. 17, 2010 and titled “GAS INJECTORS FOR CVD SYSTEMS WITH THE SAME,” the disclosure of which is incorporated herein in its entirety by this reference. The precursor gas may be preheated to more than about 500° C. In some embodiments, the precursors may be preheated to more than about 650° C., such as between about 700° C. and about 800° C. Prior to being heated, a gallium chloride precursor may be substantially comprised of gallium trichloride, which may exist in monomer form (GaCl₃) or in dimer form (Ga₂Cl₆). Upon heating and/or injection into the deposition chamber 12, at least a portion of the GaCl₃ may thermally decompose into gallium monochloride (GaCl) and other byproducts, for example. Thus, in the deposition chamber 12, the gallium chloride precursor may be substantially comprised of GaCl, although some GaCl₃ may also be present. In addition, the substrate 36 may also be heated prior to injection of the precursor gas, such as to more than about 500° C. In some embodiments, the substrate 36 may be preheated to a temperature between about 900° C. and about 1100° C.

The components of the first gas injector 100A, including the base plate 102, middle plate 104, and top plate 106A, may each be formed of any material that can sufficiently maintain its shape under operating conditions (e.g., chemicals, temperatures, flow rates, pressures, etc.). Additionally, the material of the components of the first gas injector 100A may be selected to inhibit reaction with gas (e.g., a precursor) flowing through the first gas injector 100A. By way of example and not limitation, one or more of the components may be formed of one or more of a metal, a ceramic, and a polymer. In some embodiments, one or more of the components may be at least substantially comprised of quartz, such as clear fused quartz that is fire polished, for example. In some embodiments, one or more of the components may comprise a SiC material. One or more of the components may be cleaned to reduce contaminants in the deposition chamber 12, such as with a 10% hydrofluoric (HF) acid solution, followed by a rinse with distilled and/or deionized water, for example.

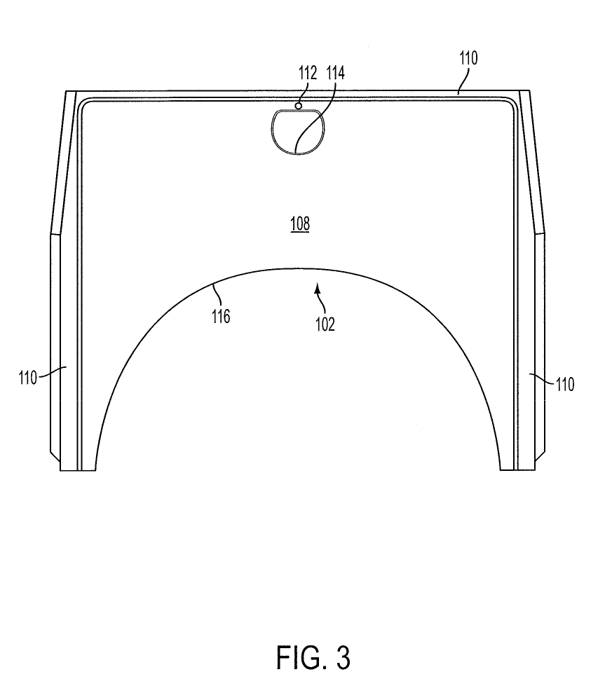

Referring to FIG. 3 in conjunction with FIG. 2, the base plate 102 may have a substantially flat upper surface 108. Sidewalls 110 may extend from the upper surface 108 and along peripheral edges of the base plate 102. A purge gas inlet 112 may extend through the base plate 102. The purge gas inlet 112 may be sized and configured to enable purge gas to be flowed through the purge gas inlet 112 from an exterior of the deposition chamber 12. A hole 114 may also extend through the base plate 102, the hole 114 sized and configured to receive a precursor gas inlet stem of the middle plate 104, as will be explained in more detail below. An outlet side 116 of the base plate 102 may be at least partially defined by a generally arcuate (e.g., semicircular) surface sized and configured to be positioned proximate a substrate 36 on which material is to be deposited.

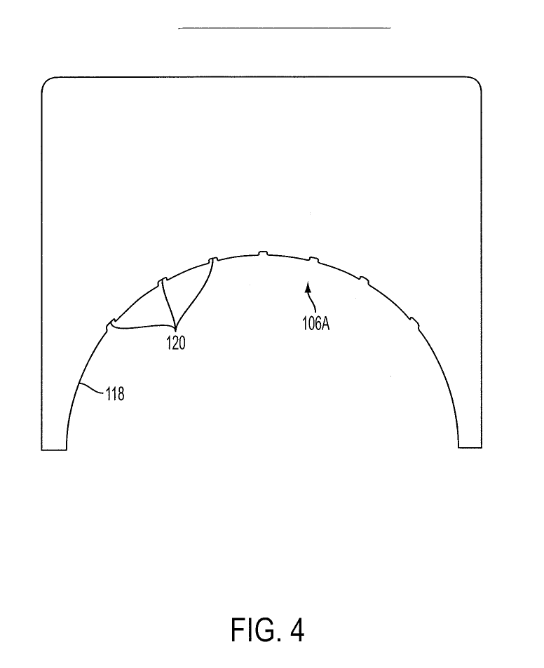

Referring to FIG. 4 in conjunction with FIG. 2, the top plate 106A may be a substantially flat member sized and configured to be assembled with the base plate 102 and middle plate 104A. In some embodiments, the top plate 106A may be sized and configured to fit over the middle plate 104A and at least partially within the sidewalls 110 of the base plate 102. The top plate 106A may have an outlet side 118 that is at least partially defined by an arcuate (e.g., generally semicircular) surface sized and configured to be positioned proximate a substrate 36 on which material is to be deposited. Notches 120 may be formed along the outlet side 118 of the top plate 106A to facilitate the formation of welds between the top plate 106A and the middle plate 104A at the notches 120.

The top plate 106A and the middle plate 104A may be adjoined together and may be configured such that one or more gas flow channels are defined between the top plate 106A and the middle plate 104A. The gas flow channels may be located and configured to generate the sheet of generally laminar flowing gas that is output by the first gas injector 100A over the surface of the substrate 36 (FIG. 1A)

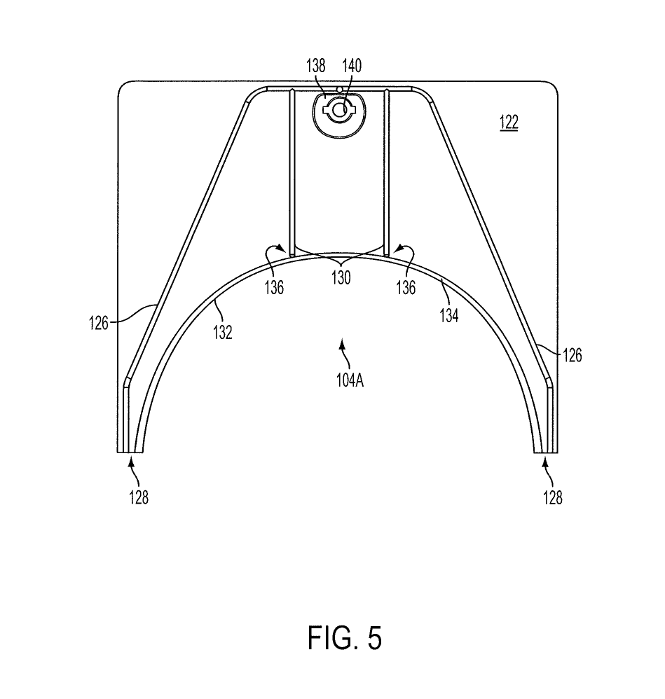

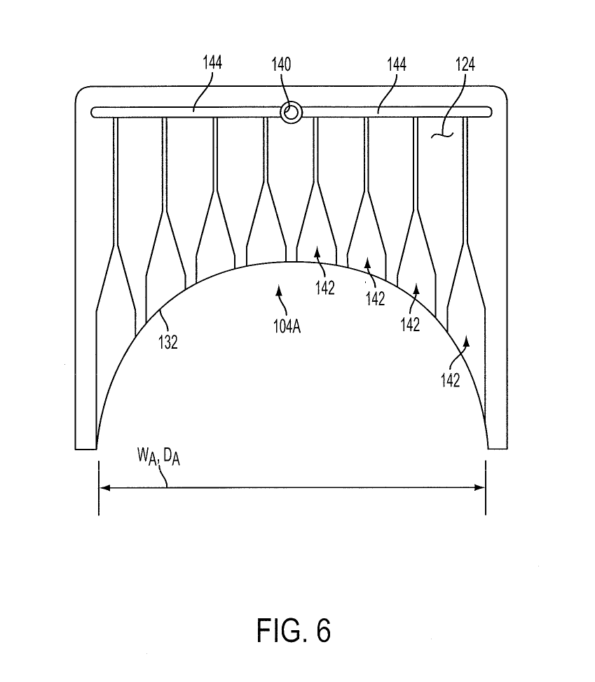

For example, referring to FIGS. 5 and 6 in conjunction with FIG. 2, the middle plate 104A of the first gas injector 100A may have a bottom surface 122 (FIG. 5) in which one or more features for flowing gas (e.g., purge gas) are formed, and an upper surface 124 (FIG. 6) in which one or more features for flowing gas (e.g., precursor gas) are formed. As shown in FIG. 5, for example, purge gas flow channels 126 may be formed in the bottom surface 122 such that purge gas may flow from the purge gas inlet 112 of the base plate 102 (FIGS. 2 and 3) to purge gas outlets 128. Thus, the purge gas flow channels 126 may be in fluid communication with the purge gas inlet 112 of the base plate 102 (FIGS. 2 and 3) when the middle plate 104A is disposed adjacent the base plate 102. Optionally, centrally located purge gas channels 130 may also be formed in the bottom surface 122 of the middle plate 104A, if purge gas is to be flowed from a central region of the first gas injector 100A. The middle plate 104A may have an outlet side 132 that is at least partially defined by an arcuate (e.g., generally semicircular) surface sized and configured to be positioned proximate a substrate 36 on which material is to be formed. A lip 134 (FIG. 5) may extend from the bottom surface 122 along the outlet side 132. When assembled with the base plate 102, the lip 134 of the middle plate 104A may hang and extend over the generally semicircular outlet side 116 of the base plate 102. As can be seen in FIG. 5, the centrally located purge gas channels 130 may have outlets 136 proximate to, but not through, the lip 134. Accordingly, during operation, purge gas flowing through the centrally located purge gas channels 130 may be dispersed by the lip 134 across the periphery of the bottom surface of the middle plate 104A at the outlet side 132 of the middle plate 104A.

As shown in FIG. 5, a gas inlet stem 138 may extend from the bottom surface 122 of the middle plate 104A. The gas inlet stem 138 may be sized and configured to be disposed at least partially within (e.g., to extend through) the hole 114 in the base plate 102 (FIGS. 2 and 3). An inlet 140 (i.e., a hole) may extend through the gas inlet stem 138 to provide fluid communication to the upper surface 124 of the middle plate 104A. The middle plate 104A may be sized and configured for assembly with the base plate 102 and the top plate 106A to form the first gas injector 100A. For example, the middle plate 104A may fit at least partially inside the sidewalls 110 (FIGS. 2 and 3) of the base plate 102 and substantially entirely under the top plate 106A when assembled therewith.

Referring to FIG. 6 in conjunction with FIG. 2, the upper surface 124 of the first middle plate 104A may include one or more features for flowing gas from the inlet 140 to the outlet side 132 of the middle plate 104A, and ultimately over a substrate 36 positioned proximate to the first gas injector 100A (FIG. 1A). For example, as shown in FIGS. 2 and 6, a plurality of longitudinally extending gas flow channels 142 may be formed in the upper surface 124 of the middle plate 104A. At least one laterally extending distribution gas flow channel 144 may provide fluid communication between the inlet 140 and each of the gas flow channels 142. As shown in FIGS. 2 and 6, the at least one lateral gas flow channel 144 may extend in a direction at least substantially perpendicular to a direction in which the plurality of gas flow channels 142 extend. In some embodiments, each of the gas flow channels 142 may be relatively narrow at the at least one lateral gas flow channel 144 and relatively wide at the outlets of the gas flow channels 142 at the outlet side 132 of the middle plate 104A, as shown in FIGS. 2 and 6. In some embodiments, each of the gas flow channels 142 may be defined by a relatively narrow inlet portion, a relatively wide outlet portion, and a diverging intermediate portion between the inlet portion and the outlet portion, as shown in FIGS. 2 and 6.

The plurality of gas flow channels 142 may enable improved distribution of gas across a substrate 36. For example, gas may be more uniformly distributed across the outlet side 132 of the middle plate 104A, and ultimately across the substrate 36. In addition, the gas flow channels 142 may be positioned across a wider extent of the outlet side 132 of the middle plate 104A compared to prior known configurations including a single central channel for flowing gas. Thus, the gas flow over the substrate 36 may be relatively more uniform compared to previously known gas injectors.

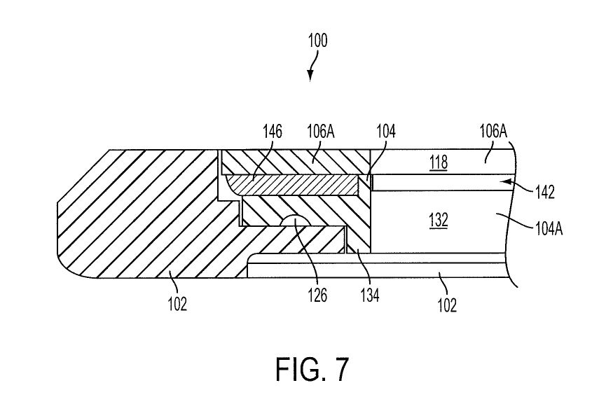

Referring to FIG. 7, a partial cross-sectional view of a portion of the first gas injector 100A is shown when assembled. A weld 146 may be formed along at least one peripheral outer edge of the middle plate 104A and top plate 106A to couple the middle plate 104A to the top plate 106. The weld 146 may be formed at least substantially continuously along all the peripheral outer edges of the middle plate 104A and top plate 106A with the exception of along the outlet side 118 of the top plate 106A and the outlet side 132 of the middle plate 104A. The weld 146 may seal the top plate 106A to the middle plate 104A and may separate the flow of the gas along the upper surface 124 of the middle plate 104A from the flow of the purge gas along the lower surface 122 of the middle plate 104A. Thus, the weld 146 may inhibit (e.g., reduce or eliminate) the formation of leaks between the top plate 106A and the middle plate 104A, and undesired flows of the gas from the gas flow channels 142 into the purge gas flow channels 126 may also be inhibited. In forming the first gas injector 100A, the top plate 106A and the middle plate 104A may be welded together prior to being assembled with the base plate 102. By way of example and not limitation, the weld 146 may be formed of quartz that is melted to adhere to the middle plate 104A and to the top plate 106A and that is subsequently solidified. As noted above, in some embodiments, additional welds may be formed between the top plate 106A and the middle plate 104A at the notches 120 formed in the top plate 106A (FIGS. 2 and 4) for mechanical stability. The adjoined middle plate 104A and top plate 106A may simply rest upon the base plate 102 in some embodiments.

Referring again to FIG. 7, the weld 146 may be a so-called “cold weld” formed by application of heat from one side of the weld 146 (e.g., a side along the peripheral outer edges of the top plate 106A and middle plate 104A). In contrast, a so-called “hot weld” is formed by application of heat from two opposing sides of the weld. Hot welds are generally more mechanically stable than cold welds. Thus, a hot weld is generally used when a weld is expected to be subjected to high mechanical stress, such as from high temperature, high pressure gradients, etc. In prior known configurations, a hot weld may be considered for use between a top plate and a base plate of a gas injector due to expected high mechanical stress in the base plate during operation. However, formation of such a hot weld is difficult or impossible due to the difficulty in accessing two opposing sides of the weld with heat sources sufficient to form the hot weld. On the other hand, a cold weld would not likely be used in prior known configurations due to the expected high mechanical stress in the base plate during operation. For at least these reasons, prior known gas injectors are generally formed of a top plate abutted against a base plate without using any welds.

Use of the middle plate 104A of the present disclosure may enable the weld 146 to be formed as a cold weld, since the expected mechanical stress in the middle plate 104A and top plate 106A may not be as much as in the base plate, and a cold weld may be expected to withstand the expected mechanical stress in the middle plate 104A and top plate 106. As noted above, the weld 146 may inhibit the formation of leaks.

Although the purge gas flow channels 126 and, optionally, the centrally located purge gas flow channels 130 are described above with reference to FIG. 5 as being formed in the bottom surface 122 of the middle plate 104A, the present disclosure is not so limited. Alternatively or in addition, one or more of the purge gas flow channels 126 and the centrally located purge gas flow channels 130 may be formed in the upper surface 108 of the base plate 102. In such configurations, the bottom surface 122 of the middle plate 104A may be substantially flat, or may also include purge gas flow channels formed therein. Similarly, although the gas flow channels 142 and the at least one lateral gas flow channel 144 are described above with reference to FIGS. 2 and 6 as being formed in the upper surface 124 of the middle plate 104A, the present disclosure is not so limited. Alternatively or in addition, one or more of the gas flow channels 142 and the at least one lateral gas flow channel 144 may be formed in the top plate 106. In such configurations, the upper surface 124 of the middle plate 104A may be substantially flat, or may also include gas flow channels formed therein. In any case, the formation of leaks between the middle plate and the top plate, which may result in undesired flow of the gas into the purge gas flow channels, may be inhibited by the weld 146, as described above.

Referring again to FIG. 6, the gas flow channels 142 of the middle plate 104A may span a maximum distance D_{A} transverse to the direction of gas flow in a gas flow plane parallel to the upper support surface of the substrate support structure 34 (FIG. 1A), such that they are configured to generate a sheet of generally laminar flowing gas having a corresponding width W_{A} transverse to the direction of gas flow in the gas flow plane parallel to the upper support surface of the substrate support structure 34. In some embodiments, the distance D_{A} and corresponding width W_{A} may be at least close to, and possibly slightly larger than, a diameter of a workpiece substrate 36 (FIG. 1A) on which material is to be deposited using the gas injector A. In some embodiments, the maximum width W_{A} of the first sheet of generally laminar flowing gas at the outlet of the first gas injector 100A may be within about 30%, within about 20%, or even about 10% of a maximum diameter of the workpiece substrate 36 used with the first gas injector 100A. As a non-limiting example, the distance D_{A} (and the width W_{A}) may be about 228.6 mm for use with workpiece substrates 36 having diameters of about 220 mm or less. Although such a gas injector 100 may be used in conjunction with workpiece substrates 36 having diameters significantly less than 220 mm (e.g., 150 mm or 100 mm), the amount of gas (e.g., precursor gas) injected by the gas injector 100A that is actually used to deposit material on such smaller workpiece substrates 36 may be decreased. Thus, the efficiency of the use of the precursor gas may be reduced when using the gas injector 100A with workpiece substrates 36 having diameters significantly less than 220 mm.

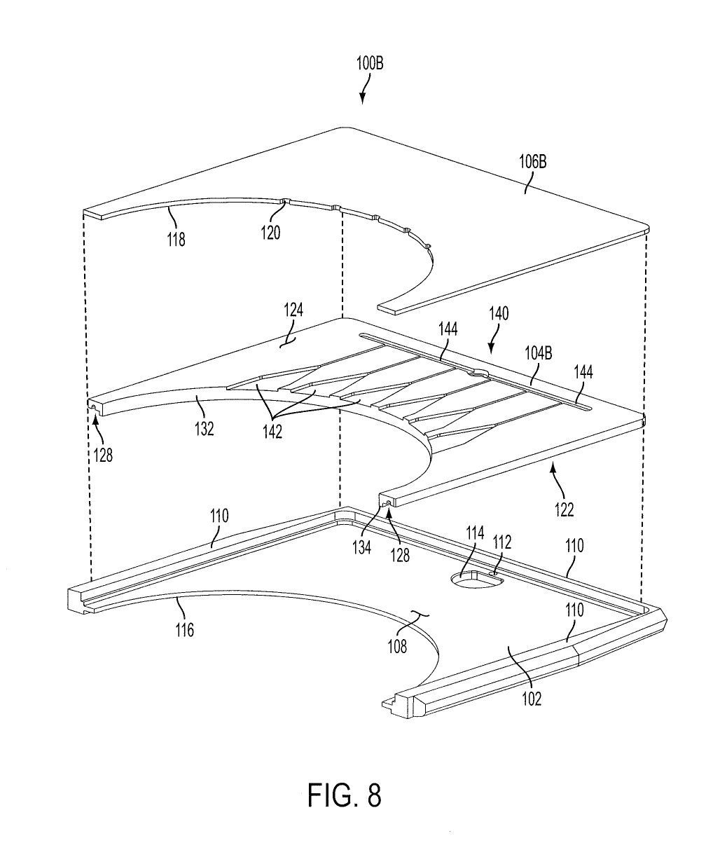

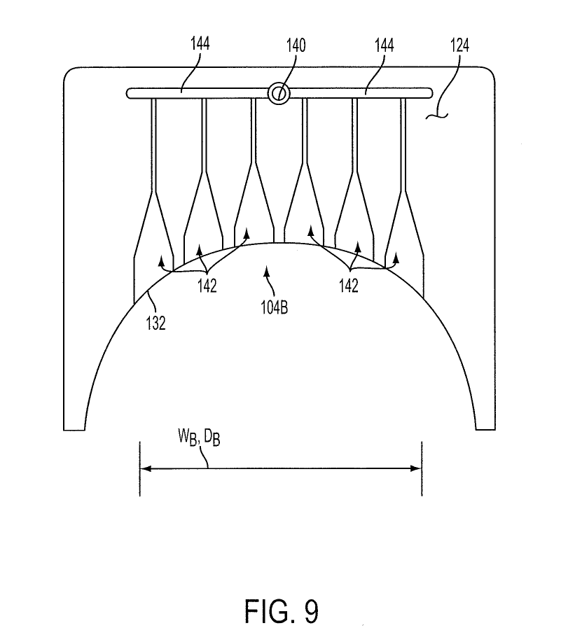

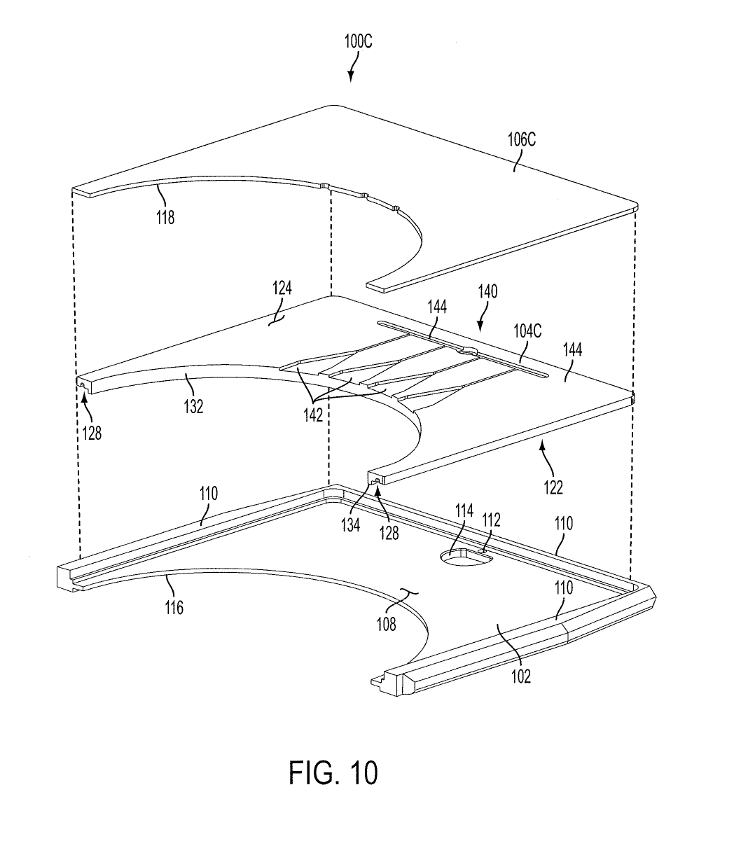

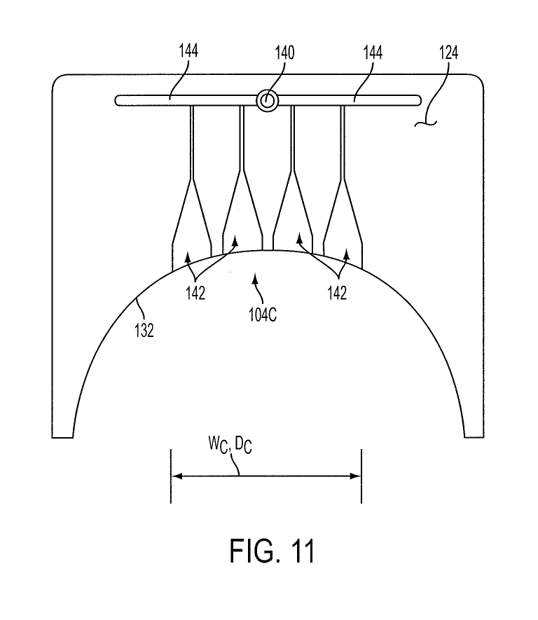

Thus, in accordance with embodiments of the present disclosure, the deposition system 100 may include one or more additional gas injectors, such as the second gas injector 100B described below with reference to FIGS. 8 and 9 and the third gas injector 100C described below with reference to FIGS. 10 and 11. The gas injectors 100A, 100B, 100C may be configured to be interchangeably seated at a common location within the deposition chamber 12. Each of the gas injectors 100A, 100B, 100C may have at least substantially identical exterior dimensions to enable the gas injectors 100A, 100B, 100C to be interchangeably seated at a common location within the deposition chamber 12.

FIG. 8 is an exploded perspective view of a second gas injector 100B that is generally similar to the first gas injector 100A, and includes a base plate 102, a second middle plate 104B, and a second top plate 106B. The second gas injector 100B, however, includes gas flow channels 142 between the middle plate 104B and the top plate 106B that span a maximum distance D_{B}, as shown in FIG. 9, which is smaller than the maximum distance D_{A}, such that they are configured to generate a narrower sheet of generally laminar flowing gas having a corresponding width W_{B} at the outlet of the gas injector 100B transverse to the direction of gas flow in a gas flow plane parallel to the upper support surface of the substrate support structure 34 (FIG. 1A). In some embodiments, the maximum width W_{B} of the second sheet of generally laminar flowing gas at the outlet of the second gas injector 100B may be within about 30%, within about 20%, or even about 10% of a maximum diameter of the workpiece substrate 36 used with the second gas injector 100B. As a non-limiting example, the maximum distance D_{B} (and the width W_{B}) may be about 182.9 mm, and the second gas injector 100B may be used with workpiece substrates 36 having diameters of about 150 mm or less.

Thus, the second maximum width W_{B} of the sheet of flowing gas output by the second gas injector 100B is smaller than the first maximum width W_{A} of the sheet of flowing gas output by the first gas injector 100A. In some embodiments, a difference between the first maximum width W_{A} and the second maximum width W_{B} may be at least about twenty-five millimeters (25 mm), at least about seventy-five millimeters (75 mm), or even at least about one hundred millimeters (100 mm).

As a non-limiting example, the second gas injector 100B may include fewer gas flow channels 142 between the adjoined second middle plate 104B and second top plate 106B compared to the number of gas flow channels 142 between the adjoined first middle plate 104A and first top plate 106A of the first injector. For example, in embodiments in which the first gas injector 100A includes eight (8) gas flow channels 142, the second gas injector 100B may include six (6) gas flow channels 142 (of at least substantially equal size and shape). In other embodiments, however, the second gas injector 100B may have the same number of gas flow channels 142 as the first gas injector 100A, but the gas flow channels 142 of the second gas injector 100B may be narrower, such that they span a smaller maximum distance D_{B}. The gas flow channel 144, which provides fluid communication between the inlet 140 and each of the gas flow channels 142, may be relatively shorter in the second gas injector 100B compared to the gas flow channel 144 in the first gas injector 100A. The second middle plate 104B may be adjoined (e.g., welded) to the second top plate 106B.

FIG. 10 is an exploded perspective view of a third gas injector 100C that is generally similar to the first gas injector 100A and the second gas injector 100C, and includes a base plate 102, a third middle plate 104C, and a third top plate 106C. The third gas injector 100C, however, includes gas flow channels 142 between the middle plate 104B and the top plate 106B that span a maximum distance D_{C}, which is smaller than each of the maximum distance D_{A} and the maximum distance D_{B}, such that they are configured to generate a yet narrower sheet of generally laminar flowing gas having a corresponding width W_{C} transverse to the direction of gas flow in a gas flow plane parallel to the upper support surface of the substrate support structure 34 (FIG. 1A). Thus, the third maximum width W_{C} of the sheet of flowing gas at the outlet of the third gas injector 100C is smaller than the first maximum width W_{A} of the sheet of flowing gas output by the first gas injector 100A and the second maximum width W_{B} of the sheet of flowing gas output by the second gas injector 100B. As a non-limiting example, the maximum distance D_{C} (and the width W_{C}) may be about 131.8 mm, and the third gas injector 100C may be used with workpiece substrates 36 having diameters of about 100 mm or less.

As a non-limiting example, the third gas injector 100C may include fewer gas flow channels 142 between the adjoined third middle plate 104C and third top plate 106C compared to the number of gas flow channels 142 between the adjoined first middle plate 104A and first top plate 106A of the first injector 100A and the adjoined second middle plate 104B and second top plate 106B of the second injector 100B. For example, in embodiments in which the first gas injector 100A includes eight (8) gas flow channels 142 and the second gas injector 100B includes six (6) gas flow channels 142, the third gas injector 100C may include four (4) gas flow channels 142 (of at least substantially equal size and shape). In other embodiments, however, the third gas injector 100C may have the same number of gas flow channels 142 as each of the first gas injector 100A and the second gas injector 100B, but the gas flow channels 142 of the third gas injector 100C may be narrower, such that they span a smaller maximum distance D_{C}. The gas flow channel 144, which provides fluid communication between the inlet 140 and each of the gas flow channels 142, may be relatively shorter in the third gas injector 100C compared to the gas flow channel 144 in each of the first gas injector 100A and the second gas injector 100B. As in the first and second gas injectors 100A, 100B, the third middle plate 104C may be adjoined (e.g., welded) to the third top plate 106C.

In some embodiments, the same base plate 102 may be used to form each of the first gas injector 100A, the second gas injector 100B, and the third gas injector 100C. In other words, the deposition system 10 may include a single base plate 102, and two or more assemblies, each including a middle plate 104A, 104B, 104C and a corresponding and adjoined top plate 104A, 104B, 104C. Such assemblies may be interchangeably used with the single base plate 102, and may simply rest upon the base plate 102 during use. In yet further embodiments, the gas injectors 100A, 100B, 100C may not include a base plate 102, but may only include the adjoined middle plates 104A, 104B, 104C and top plates 106A, 106B, 106C. In other words, the base plate 102 is optional and may be eliminated from the gas injectors 100A, 100R, 100C in further embodiments.

Referring again to FIG. 1A, deposition systems 100 that include modular, interchangeable gas injectors 100A, 100B, 100C as described herein may be used to deposit materials on workpiece substrates 36 of different sizes while maintaining efficient use of precursor gases. In accordance with such methods, a first gas injector 100A may be installed within the deposition chamber 12, and a first workpiece substrate 36 may be positioned on the workpiece support structure 34 within the deposition chamber 12.

A first sheet of generally laminar flowing gas may be generated over the first workpiece substrate 36 using the first gas injector 100A. As described with reference to FIG. 6, the first sheet of generally laminar flowing gas may have a first maximum width W_{A} transverse to the direction of the gas flow in the first sheet of generally laminar flowing gas. After depositing material on the first workpiece substrate 36 using the precursor gas injected over the substrate 36 using the first gas injector 100A, the first workpiece substrate 36 may be removed from the deposition chamber 12.

A second gas injector 100B may be installed within the deposition chamber 12, and a second workpiece substrate 36 may be positioned on the workpiece support structure 34 within the deposition chamber 12. The second workpiece substrate 36 may have a smaller diameter than the first workpiece substrate 36.

A second sheet of generally laminar flowing gas may be generated over the second workpiece substrate 36 using the second gas injector 100B. As described with reference to FIG. 9, the second sheet of generally laminar flowing gas may have a second maximum width W_{B} transverse to the direction of the gas flow in the second sheet of generally laminar flowing gas, and the second maximum width W_{B} may be smaller than the first maximum width W_{A}. After depositing material on the second workpiece substrate 36 using the precursor gas injected over the substrate 36 using the second gas injector 100B, the second workpiece substrate 36 may be removed from the deposition chamber 12.

The third gas injector 100C optionally may also be interchangeably used with the deposition system 10 to deposit material on yet smaller workpiece substrates 36 in a similar manner.

Additional non-limiting example embodiments of the present disclosure are set forth below.

### Embodiment 1

A deposition system, comprising: a deposition chamber; a substrate support structure having an upper support surface configured to support a substrate within the deposition chamber; and at least two gas injectors each configured to be interchangeably seated at a common location within the deposition chamber, each of the at least two gas injectors configured to generate a sheet of generally laminar flowing gas over the substrate support structure during operation of the deposition system, a first gas injector of the at least two gas injectors including two adjoining plates defining one or more gas flow channels therebetween located and configured to generate a sheet of generally laminar flowing gas at an outlet of the first gas injector having a first maximum width transverse to a direction of gas flow in a gas flow plane parallel to the upper support surface of the substrate support structure, a second gas injector of the at least two gas injectors including two adjoining plates therebetween defining one or more gas flow channels located and configured to generate a second sheet of generally laminar flowing gas having a second maximum width at an outlet of the second gas injector transverse to the direction of gas flow in the gas flow plane, the second maximum width being smaller than the first maximum width.

### Embodiment 2

The deposition system of Embodiment 1, wherein the one or more gas flow channels defined between the two adjoining plates of the first gas injector have outlets spanning a first distance transverse to a direction of gas flow in the gas flow plane, and wherein the one or more gas flow channels defined between the two adjoining plates of the second gas injector have outlets spanning a second distance transverse to the direction of gas flow in the gas flow plane, the second distance being smaller than the first distance.

### Embodiment 3

The deposition system of Embodiment 1 or Embodiment 2, wherein a difference between the first maximum width and the second maximum width is at least about twenty-five millimeters (25 mm).

### Embodiment 4

The deposition system of Embodiment 3, wherein the difference between the first maximum width and the second maximum width is at least about seventy-five millimeters (75 mm).

### Embodiment 5

The deposition system of Embodiment 4, wherein the difference between the first maximum width and the second maximum width is at least about one hundred millimeters (100 mm).

### Embodiment 6

The deposition system of any one of Embodiments 1 through 5, wherein the two adjoining plates of each of the at least two gas injectors define a laterally extending distribution gas flow channel and a plurality of longitudinally extending gas flow channels extending between the distribution gas flow channel and an outlet.

### Embodiment 7

The deposition system of Embodiment 6, wherein the two adjoining plates of the first gas injector define a first number of longitudinally extending gas flow channels extending between the distribution gas flow channel and the outlet, wherein the two adjoining plates of the second gas injector define a second number of longitudinally extending gas flow channels extending between the distribution gas flow channel and the outlet, and wherein the second number is less than the first number.

### Embodiment 8

The deposition system of Embodiment 6, wherein the two adjoining plates of the first gas injector define a first number of relatively wider longitudinally extending gas flow channels extending between the distribution gas flow channel and the outlet, wherein the two adjoining plates of the second gas injector define a second number of relatively narrower longitudinally extending gas flow channels extending between the distribution gas flow channel and the outlet.

### Embodiment 9

The deposition system of any one of Embodiments 6 through 8, wherein each of the longitudinally extending gas flow channels of the first and second gas injectors have a relatively narrow inlet portion, a relatively wide outlet portion, and a diverging intermediate portion.

### Embodiment 10

The deposition system of any one of Embodiments 1 through 9, wherein each of the at least two gas injectors comprises a third plate coupled with the two adjoining plates such that an additional gas flow channel is defined between the third plate and one of the two adjoining plates.

### Embodiment 11

The deposition system of any one of Embodiments 1 through 10, wherein an outlet of each of the at least two gas injectors comprises a semicircular surface having a radius.

### Embodiment 12

The deposition system of any one of Embodiments 1 through 11, wherein each of the first gas injector and the second gas injector have at least substantially identical exterior dimensions.

### Embodiment 13

A method of forming a deposition system including providing a deposition chamber, and providing a substrate support structure within the deposition chamber having an upper support surface configured to support a substrate, the method further comprising: forming a first gas injector by forming two plates and adjoining the two plates together such that one or more gas flow channels are defined between the adjoined plates, the one or more gas flow channels located and configured to generate a first sheet of generally laminar flowing gas having a first maximum width transverse to a direction of gas flow in a gas flow plane parallel to the upper support surface of the substrate support structure; forming a second gas injector by forming two plates and adjoining the two plates together such that one or more gas flow channels are defined between the adjoined plates, the one or more gas flow channels located and configured to generate a second sheet of generally laminar flowing gas having a second maximum width transverse to the direction of gas flow in the gas flow plane parallel to the upper support surface of the substrate support structure, the second maximum width being smaller than the first maximum width; and configuring the first gas injector and the second gas injector to be interchangeably used at a common location within the deposition chamber.

### Embodiment 14

The method of Embodiment 13, further comprising forming the first gas injector and the second gas injector such that a difference between the first maximum width and the second maximum width is at least about twenty-five millimeters (25 mm).

### Embodiment 15

The method of Embodiment 13 or Embodiment 14, further comprising forming each of the first gas injector and the second gas injector to include a laterally extending distribution gas flow channel and a plurality of longitudinally extending gas flow channels extending between the distribution gas flow channel and an outlet.

### Embodiment 16

The method of Embodiment 15, further comprising forming the second gas injector to have fewer longitudinally extending gas flow channels than the first gas injector.

### Embodiment 17

The method of Embodiment 15 or Embodiment 16, further comprising forming each of the longitudinally extending gas flow channels of at least one of the first gas injector and the second gas injector to have a relatively narrow inlet portion, a relatively wide outlet portion, and a diverging intermediate portion.

### Embodiment 18

The method of any one of Embodiments 13 through 17, further comprising forming an outlet of each of the first gas injector and the second gas injector to comprise a semicircular surface having a radius.

### Embodiment 19

The method of any one of Embodiments 13 through 18, further comprising forming the first gas injector and the second gas injector to have at least substantially identical exterior dimensions.

### Embodiment 20

A method of using a deposition system, the method comprising: installing a first gas injector within a deposition chamber, the first gas injector comprising two adjoining plates defining one or more gas flow channels between the two adjoining plates; positioning a first substrate within the deposition chamber; generating a first sheet of generally laminar flowing gas over the first substrate using the first gas injector and depositing material on the first substrate using the first sheet of generally laminar flowing gas, the first sheet of generally laminar flowing gas having a first maximum width transverse to a direction of gas flow in the first sheet of generally laminar flowing gas; removing the first substrate from the deposition chamber after depositing material on the first substrate; installing a second gas injector within the deposition chamber, the second gas injector comprising two adjoining plates defining one or more gas flow channels between the two adjoining plates; positioning a second substrate within the deposition chamber, the second substrate having a diameter smaller than a diameter of the first substrate; and generating a second sheet of generally laminar flowing gas over the second substrate using the second gas injector and depositing material on the second substrate using the second sheet of generally laminar flowing gas, the second sheet of generally laminar flowing gas having a second maximum width transverse to a direction of gas flow in the second sheet of generally laminar flowing gas, the second maximum width being smaller than the first maximum width.

### Embodiment 21

The method of Embodiment 20, wherein the maximum width of the first sheet of generally laminar flowing gas is within about 10% of a maximum diameter of the first substrate.

### Embodiment 22

The method of Embodiment 20 or Embodiment 21, wherein the maximum width of the second sheet of generally laminar flowing gas is within about 10% of a maximum diameter of the second substrate.

The example embodiments of the disclosure described above do not limit the scope of the invention, since these embodiments are merely examples of embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A deposition system, comprising:
a deposition chamber;
a substrate support structure having an upper support surface configured to support a substrate within the deposition chamber; and
at least two gas injectors each configured to be interchangeably seated at a common location within the deposition chamber, each of the at least two gas injectors configured to generate a sheet of generally laminar flowing gas over the substrate support structure during operation of the deposition system, a first gas injector of the at least two gas injectors including two adjoining plates defining one or more gas flow channels therebetween located and configured to generate a sheet of generally laminar flowing gas having a first maximum width at an outlet of the first gas injector transverse to a direction of gas flow in a gas flow plane parallel to the upper support surface of the substrate support structure, a second gas injector of the at least two gas injectors including two adjoining plates therebetween defining one or more gas flow channels located and configured to generate a second sheet of generally laminar flowing gas having a second maximum width at an outlet of the second gas injector transverse to the direction of gas flow in the gas flow plane, the second maximum width being smaller than the first maximum width.

2. The deposition system of claim 1, wherein the one or more gas flow channels defined between the two adjoining plates of the first gas injector have outlets spanning a first distance transverse to a direction of gas flow in the gas flow plane, and wherein the one or more gas flow channels defined between the two adjoining plates of the second gas injector have outlets spanning a second distance transverse to the direction of gas flow in the gas flow plane, the second distance being smaller than the first distance.

3. The deposition system of claim 1, wherein the two adjoining plates of each of the at least two gas injectors define a laterally extending distribution gas flow channel and a plurality of longitudinally extending gas flow channels extending between the distribution gas flow channel and an outlet.

4. The deposition system of claim 3, wherein the two adjoining plates of the first gas injector define a first number of longitudinally extending gas flow channels extending between the distribution gas flow channel and the outlet, wherein the two adjoining plates of the second gas injector define a second number of longitudinally extending gas flow channels extending between the distribution gas flow channel and the outlet, and wherein the second number is less than the first number.

5. The deposition system of claim 3, wherein the two adjoining plates of the first gas injector define a first number of relatively wider longitudinally extending gas flow channels extending between the distribution gas flow channel and the outlet, wherein the two adjoining plates of the second gas injector define a second number of relatively narrower longitudinally extending gas flow channels extending between the distribution gas flow channel and the outlet.

6. The deposition system of claim 3, wherein each of the longitudinally extending gas flow channels of the first and second gas injectors have a relatively narrow inlet portion, a relatively wide outlet portion, and a diverging intermediate portion.

7. The deposition system of claim 1, wherein each of the at least two gas injectors comprises a third plate coupled with the two adjoining plates such that an additional gas flow channel is defined between the third plate and one of the two adjoining plates.

8. The deposition system of claim 1, wherein an outlet of each of the at least two gas injectors comprises a semicircular surface having a radius.

9. The deposition system of claim 1, wherein each of the first gas injector and the second gas injector have at least substantially identical exterior dimensions.

10. A method of forming a deposition system including providing a deposition chamber, and providing a substrate support structure within the deposition chamber having an upper support surface configured to support a substrate, the method further comprising:
forming a first gas injector by forming two plates and adjoining the two plates together such that one or more gas flow channels are defined between the adjoined plates, the one or more gas flow channels located and configured to generate a first sheet of generally laminar flowing gas having a first maximum width transverse to a direction of gas flow in a gas flow plane parallel to the upper support surface of the substrate support structure;
forming a second gas injector by forming two plates and adjoining the two plates together such that one or more gas flow channels are defined between the adjoined plates, the one or more gas flow channels located and configured to generate a second sheet of generally laminar flowing gas having a second maximum width transverse to the direction of gas flow in the gas flow plane parallel to the upper support surface of the substrate support structure, the second maximum width being smaller than the first maximum width; and
configuring the first gas injector and the second gas injector to be interchangeably used at a common location within the deposition chamber.

11. The method of claim 10, further comprising forming each of the first gas injector and the second gas injector to include a laterally extending distribution gas flow channel and a plurality of longitudinally extending gas flow channels extending between the distribution gas flow channel and an outlet.

12. The method of claim 11, further comprising forming the second gas injector to have fewer longitudinally extending gas flow channels than the first gas injector.

13. The method of claim 11, further comprising forming each of the longitudinally extending gas flow channels of at least one of the first gas injector and the second gas injector to have a relatively narrow inlet portion, a relatively wide outlet portion, and a diverging intermediate portion.

14. The method of claim 10, further comprising forming an outlet of each of the first gas injector and the second gas injector to comprise a semicircular surface having a radius.

15. The method of claim 10, further comprising forming the first gas injector and the second gas injector to have at least substantially identical exterior dimensions.

16. The method of claim 10, further comprising forming the first gas injector and the second gas injector such that a difference between the first maximum width and the second maximum width is at least about twenty-five millimeters (25 mm).

17. The deposition system of claim 1, wherein a difference between the first maximum width and the second maximum width is at least about twenty-five millimeters (25 mm).

18. A method of using a deposition system, the method comprising:
installing a first gas injector within a deposition chamber, the first gas injector comprising two adjoining plates defining one or more gas flow channels between the two adjoining plates;
positioning a first substrate within the deposition chamber;
generating a first sheet of generally laminar flowing gas over the first substrate using the first gas injector and depositing material on the first substrate using the first sheet of generally laminar flowing gas, the first sheet of generally laminar flowing gas having a first maximum width transverse to a direction of gas flow in the first sheet of generally laminar flowing gas;
removing the first substrate from the deposition chamber after depositing material on the first substrate;
installing a second gas injector within the deposition chamber, the second gas injector comprising two adjoining plates defining one or more gas flow channels between the two adjoining plates;
positioning a second substrate within the deposition chamber, the second substrate having a diameter smaller than a diameter of the first substrate; and
generating a second sheet of generally laminar flowing gas over the second substrate using the second gas injector and depositing material on the second substrate using the second sheet of generally laminar flowing gas, the second sheet of generally laminar flowing gas having a second maximum width transverse to a direction of gas flow in the second sheet of generally laminar flowing gas, the second maximum width being smaller than the first maximum width.

19. The method of claim 18, wherein the maximum width of the first sheet of generally laminar flowing gas is within about 10% of a maximum diameter of the first substrate.

20. The method of claim 19, wherein the maximum width of the second sheet of generally laminar flowing gas is within about 10% of a maximum diameter of the second substrate.
